(19) United States
(12) Patent Application Publication
(10) Pub. No.: US 2019/0292409 A1
(43) Pub. Date: Sep. 26, 2019

(54) CHEMICAL MECHANICAL POLISHING COMPOSITION AND METHOD OF MANUFACTURING CIRCUIT BOARD

(71) Applicant: JSR Corporation, Minato-ku (JP)

(72) Inventors: Eiichirou KUNITANI, Minato-ku (JP); Kazuhiro Tanaka, Minato-ku (JP); Masahiro Noda, Minato-ku (JP); Tatsuya Yamanaka, Minato-ku (JP)

(73) Assignee: JSR Corporation, Minato-ku (JP)

(21) Appl. No.: 16/360,822

(22) Filed: Mar. 21, 2019

(30) Foreign Application Priority Data
Mar. 22, 2018 (JP) 2018-054547

(51) Int. Cl. C09G 1/02; H05K 3/06

(52) U.S. Cl. CPC C09G 1/02; H05K 3/06

(57) ABSTRACT

Provided is a chemical mechanical polishing composition to be used for forming a circuit board including a resin substrate on which a wiring layer containing copper or a copper alloy is provided, the chemical mechanical polishing composition including: (A) at least one selected from a group consisting of carboxyl group-containing organic acids and salts thereof; (B) a basic compound having a first acid dissociation constant (pKa) of 9 or more; and (C) abrasive grains, wherein the component (A) has a complex stability constant with copper of 5 or less, and wherein the chemical mechanical polishing composition has a pH value of from 1 to 3.

Japanese Patent Application No. 2018-054547, filed on Mar. 22, 2018, is hereby incorporated by reference in its entirety.

### BACKGROUND OF THE INVENTION

The present invention relates to a chemical mechanical polishing composition, and a method of manufacturing a circuit board using the composition.

In recent years, downsizing of an electronic device has been advanced, and there has been a demand for further miniaturization and multilayering of a constituent semiconductor device thereof and a circuit board for mounting the semiconductor device. A multilayer circuit board (multilayered circuit board) generally has a three-dimensional wiring structure in which a plurality of circuit boards each having formed thereon a wiring pattern are stacked. When the multilayer circuit board or the circuit board has a nonuniform thickness or insufficient planarity, a problem such as a connection failure may occur at the time of mounting. Therefore, the circuit boards serving as the constituent layers of the multilayer circuit board each need to be formed so as to have a uniform thickness and a planar surface, in order to prevent unevenness and a curve from being caused when the circuit boards are stacked to form the multilayer circuit board.

Hitherto, in order to achieve high integration and densification of a circuit board, a half-etching method (HE method) using an etchant has been used in a circuit board manufacturing step. The HE method involves complicated control of etching, resulting in a high processing cost, and hence there is a need for alternative technologies. As one of the alternative technologies, there is known chemical mechanical polishing (CMP), which is performed for the purpose of planarizing a circuit board through removal of an excess film thickness.

The CMP is a technology essential to a technology for manufacturing an ultra large scale integrated circuit (ULSI) or the like. However, in the CMP for the ULSI, a removal rate of a wiring material, such as a copper film, is as low as 0.3 μm/min or less. In the CMP for a circuit board, a large amount of the wiring material needs to be removed, and hence it is required that the wiring material be removed at a high rate and with high efficiency. In order to meet such requirement, for example, in JP-A-2010-021529, there is disclosed a water-based dispersion for chemical mechanical polishing for forming a circuit board, containing an organic acid, a nitrogen-containing heterocyclic compound, and the like.

The water-based dispersion for chemical mechanical polishing of JP-A-2010-021529 in the related-art circuit board formation allows a wiring metal, such as a copper film, to be polished at a high rate, and besides, can make the planarity of the circuit board satisfactory. However, the water-based dispersion for chemical mechanical polishing of JP-A-2010-021529 has a problem in that the organic acid contained therein chemically acts on a surface to be polished, and the surface to be polished is etched to become vulnerable to damage, such as corrosion. Suppression of the damage, such as corrosion, due to the etching on the surface to be polished of the circuit board as described above has been in strong demand in recent years with a view to suppressing the occurrence of the problem such as the connection failure at the time of mounting as well.

### SUMMARY

The invention can provide a chemical mechanical polishing composition that allows a circuit board including a resin substrate on which a wiring layer containing copper or a copper alloy is provided to be polished at a high rate, and besides, can reduce the occurrence of damage and corrosion due to etching on the surface to be polished of the circuit board, and a method of manufacturing a circuit board using the composition.

According to a first aspect of the invention, there is provided a chemical mechanical polishing composition to be used for forming a circuit board including a resin substrate on which a wiring layer containing copper or a copper alloy is provided, the chemical mechanical polishing composition including:
(A) at least one selected from a group consisting of carboxyl group-containing organic acids and salts thereof;
(B) a basic compound having a first acid dissociation constant (pKa) of 9 or more; and
(C) abrasive grains,
the component (A) having a complex stability constant with copper of 5 or less, and
the chemical mechanical polishing composition having a pH value of from 1 to 3.

According to a second aspect of the invention, there is provided a method of manufacturing a circuit board, the method including:
performing chemical mechanical polishing by using the above chemical mechanical polishing composition.

### BRIEF DESCRIPTION OF THE SEVERAL VIEWS OF THE DRAWING

FIG. 1 is a cross-sectional view for schematically illustrating a manufacturing step for a circuit board according to one embodiment of the invention.

FIG. 2 is a cross-sectional view for schematically illustrating a manufacturing step for a circuit board according to one embodiment of the invention.

FIG. 3 is a cross-sectional view for schematically illustrating a manufacturing step for a circuit board according to one embodiment of the invention.

FIG. 4 is a cross-sectional view for schematically illustrating a manufacturing step for a circuit board according to one embodiment of the invention.

FIG. 5 is a cross-sectional view for schematically illustrating a manufacturing step for a circuit board according to one embodiment of the invention.

FIG. 6 is a perspective view for schematically illustrating a chemical mechanical polishing apparatus suitable for use in a chemical mechanical polishing step.

### DETAILED DESCRIPTION OF THE EMBODIMENT

The invention has been made in order to solve at least part of the above-mentioned problems, and can be implemented as any one of the following embodiments.

According to one embodiment of the invention, there is provided a chemical mechanical polishing composition to be used for forming a circuit board including a resin substrate on which a wiring layer containing copper or a copper alloy is provided, the chemical mechanical polishing composition including:
(A) at least one selected from a group consisting of carboxyl group-containing organic acids and salts thereof;
(B) a basic compound having a first acid dissociation constant (pKa) of 9 or more; and
(C) abrasive grains,
the component (A) having a complex stability constant with copper of 5 or less, and
the chemical mechanical polishing composition having a pH value of from 1 to 3.

In the above chemical mechanical polishing composition, the abrasive grains of the component (C) may each have an absolute value of a zeta potential of 5 mV or more in the chemical mechanical polishing composition.

In the above chemical mechanical polishing composition, the component (A) may contain at least one selected from a group consisting of maleic acid, tartaric acid, malic acid, and salts thereof.

In the above chemical mechanical polishing composition, the component (B) may contain at least one selected from a group consisting of a metal hydroxide, an amine, and ammonia.

In the above chemical mechanical polishing composition, the abrasive grains of the component (C) may be silica particles.

In the above chemical mechanical polishing composition, the silica particles may each have at least one functional group selected from a group consisting of a sulfo group, an amino group, and salts thereof.

In the above chemical mechanical polishing composition, the abrasive grains of the component (C) may have an average particle diameter of 40 nm or more and 100 nm or less.

According to one embodiment of the invention, there is provided a method of manufacturing a circuit board, the method including:
performing chemical mechanical polishing by using the above chemical mechanical polishing composition.

According to the above chemical mechanical polishing composition, a circuit board including a resin substrate on which a wiring layer containing copper or a copper alloy is provided can be polished at a high rate, and besides, damage due to etching and corrosion on the surface to be polished of the circuit board can be reduced, and hence a satisfactory surface state can be achieved.

According to the above method of manufacturing a circuit board, the circuit board can be polished at a high rate, and hence the circuit board can be manufactured with a high throughput. In addition, damage due to etching and corrosion on the surface to be polished can be reduced, and hence a problem such as a connection failure hardly occurs at the time of mounting.

Embodiments of the invention are described in detail below. It is noted that the invention is not limited to the following embodiments, and includes various modifications within the scope of the invention.

Herein, a numerical range described with “from A to B” is meant to include a numerical value A as a lower limit value and a numerical value B as an upper limit value.

A “resin” in the invention is not particularly limited as long as the resin is a resin to be used for producing a circuit board, and examples thereof include polyimide-based, phenol-based, epoxy-based, melamine-based, urea-based, unsaturated polyester-based, diallyl phthalate-based, polyurethane-based, silicon-based, and other thermosetting resins, and crosslinked curable resins, such as novolacs, each obtained by curing a thermoplastic resin with a crosslinking agent. Specific examples of the curable resins include photosensitive resins, such as a cyclized rubber-bisazide-based resin, a DNQ-novolac resin-based resin, a chemical amplification-type resin-based resin, polyhydroxystyrene, polymethyl methacrylate, and a fluorine resin.

The term “wiring metal” in the invention refers to copper or a copper alloy.

The term “complex stability constant” in the invention refers to the value of k₁·k₂·k₃ . . . kₙ=K=[MAₙ]/[M][A]ⁿ in the case where, when a metal ion M and a ligand A react with each other in steps to produce a complex, such as MAₙ, the equilibrium constant of each step is expressed with respective molar concentrations (mol/L) as k₁=[MA]/[M][A], k₂=[MA₂]/[MA][A], . . . , kₙ=[MAₙ]/[MAₙ₋₁][A].

The value of the “first acid dissociation constant (pKa)” of a basic compound in the invention is the value of the first acid dissociation constant of the conjugate acid of the basic compound.

### 1. Chemical Mechanical Polishing Composition

The chemical mechanical polishing composition according to one embodiment of the invention includes: (A) at least one selected from a group consisting of carboxyl group-containing organic acids and salts thereof; (B) a basic compound having a first acid dissociation constant (pKa) of 9 or more; and (C) abrasive grains, wherein the component (A) has a complex stability constant with copper of 5 or less, and wherein the chemical mechanical polishing composition has a pH value of from 1 to 3. Each component to be contained in the chemical mechanical polishing composition is described in detail below.

### 1.1. (A) Organic Acid and Salt Thereof

The chemical mechanical polishing composition contains (A) at least one selected from a group consisting of carboxyl group-containing organic acids and salts thereof (herein sometimes referred to as “component (A)”). A function of the component (A) is, for example, to improve the polishing rate of a wiring metal. Another function of the component (A) is, for example, to reduce damage due to etching and corrosion on the surface to be polished of a circuit board.

The component (A) has a complex stability constant with copper serving as a wiring metal of 5 or less. A larger value of the complex stability constant with copper means that the formation of a complex of the component (A) and a copper ion is more promoted, suggesting that the component (A) has a high ability to form a copper complex. Therefore, when the complex stability constant of the component (A) with copper is 5 or less, the component (A) hardly forms a complex with a copper ion in the vicinity of a wiring layer. As a result, the chance of the component (A) remaining in the vicinity of the wiring layer is reduced, and hence damage due to etching and corrosion on the surface to be polished of a circuit board can be reduced. Meanwhile, when the complex stability constant of the component (A) with copper is more than 5, the component (A) is liable to form a complex with a copper ion in the vicinity of the wiring layer. As a result, the chance of the component (A) remaining in the vicinity of the wiring layer is increased, and hence damage due to etching and corrosion on the surface to be polished of a circuit board is liable to be increased, and besides, the planarity of the surface to be polished is impaired in some cases.

Specific examples of the component (A) include adipic acid (3.35), formic acid (1.98), fumaric acid (2.51), glutaric acid (2.40), glycolic acid (2.81), 3-methylbutanoic acid (2.08), itaconic acid (2.80), lactic acid (3.02), maleic acid (3.90), malic acid (3.4), propionic acid (2.2), succinic acid (3.3), tartaric acid (3.2), and salts thereof. The salts thereof encompass not only salts of the organic acids given as examples above, but also an organic acid salt formed through a reaction with a separately added base in the chemical mechanical polishing composition. Those components (A) may be used alone or in combination thereof at any ratio. Numbers in parentheses in this paragraph each represent a complex stability constant with copper.

Of the components (A) given as examples above, at least one selected from a group consisting of maleic acid, tartaric acid, malic acid, and salts thereof is preferred because of having high effects of improving the polishing rate of the wiring metal and reducing damage due to etching and corrosion on the surface to be polished.

The lower limit value of the content of the component (A) is preferably 1 mass %, more preferably 3 mass %, particularly preferably 4 mass % with respect to the total mass of the chemical mechanical polishing composition. When the content of the component (A) is equal to or higher than the above-mentioned value, the effect of improving the polishing rate of the wiring metal is obtained in some cases. Meanwhile, the upper limit value of the content of the component (A) is preferably 15 mass %, more preferably 12 mass %, particularly preferably 10.5 mass % with respect to the total mass of the chemical mechanical polishing composition. When the content of the component (A) is equal to or lower than the above-mentioned value, damage due to etching and corrosion on the surface to be polished can be reduced, and the planarity of the surface to be polished becomes satisfactory in some cases.

### 1.2. (B) Basic Compound

The chemical mechanical polishing composition contains (B) a basic compound having a first acid dissociation constant (pKa) of 9 or more (herein sometimes referred to as “component (B)”). One function of the component (B) is, for example, to suppress excessive etching on the surface to be polished caused by the component (A) and reduce the occurrence of corrosion on the surface to be polished, to thereby make the surface state of the surface to be polished after a polishing step satisfactory. The component (B) has a first acid dissociation constant (pKa) of 9 or more, and hence has a low chemical action on copper or a copper alloy under an acidic condition, thus being able to effectively protect the surface to be polished while reducing damage due to etching and corrosion on the surface to be polished caused by the component (A).

The component (B) is preferably at least one selected from a group consisting of a metal hydroxide, an amine, and ammonia. Specific examples of the component (B) include: metal hydroxides, such as sodium hydroxide, potassium hydroxide, rubidium hydroxide, and cesium hydroxide; organic ammonium salts, such as tetramethylammonium hydroxide (TMAH); alkanolamines, such as monoethanolamine, diethanolamine, triethanolamine, N-methyl ethanol amine, N-methyl-N,N-diethanolamine, N,N-dimethylethanolamine, N,N-di ethyl ethanolamine, N,N-dibutylethanolamine, N-(β-aminoethyl)ethanolamine, N-ethyl ethanolamine, monopropanolamine, dipropanolamine, tripropanolamine, monoisopropanolamine, diisopropanolamine, and triisopropanolamine; primary amines, such as methylamine, ethylamine, propylamine, butylamine, pentylamine, and 1,3-propanediamine; secondary amines, such as piperidine and piperazine; tertiary amines, such as trimethylamine and triethylamine-ammonia; and ammonia. Those components (B) may be used alone or as a mixture thereof.

The lower limit value of the content of the component (B) is preferably 0.01 mass %, more preferably 0.1 mass %, particularly preferably 0.2 mass % with respect to the total mass of the chemical mechanical polishing composition. When the content of the component (B) is equal to or higher than the above-mentioned value, the effect of reducing damage due to etching and corrosion on the surface to be polished is obtained in some cases. Meanwhile, the upper limit value of the content of the component (B) is preferably 1 mass %, more preferably 0.8 mass %, particularly preferably 0.5 mass % with respect to the total mass of the chemical mechanical polishing composition. When the content of the component (B) is equal to or lower than the above-mentioned value, a circuit board including a resin substrate on which a wiring layer containing copper or a copper alloy is provided can be polished at a high rate without an excessive influence on the etching action of the component (A) in some cases.

In the chemical mechanical polishing composition, when the content of the component (A) is represented by M_{A} mass % and the content of the component (B) is represented by M_{B} mass %, the content ratio M_{A}/M_{B} of the component (A) to the component (B) is preferably from 4 to 40, more preferably from 4.5 to 30, particularly preferably from 5 to 25. When M_{A}/M_{B} falls within the above-mentioned range, an increase in polishing rate of a circuit board and a reduction in damage to the surface to be polished can both be achieved with ease without an excessive influence of the component (B) on the etching action of the component (A) in some cases.

1.3. (C) Abrasive Grains The chemical mechanical polishing composition contains (C) abrasive grains (herein sometimes referred to as “component (C)”). The component (C) has a function of mechanically polishing the surface to be polished to increase the polishing rate.

Examples of the component (C) include silica particles, alumina particles, titania particles, zirconia particles, ceria particles, and calcium carbonate particles. Of those, silica particles are preferred because of having a high effect of reducing polishing flaws, such as scratches, on the surface to be polished.

Examples of the silica particles include silica particles of colloidal silica, fumed silica, and the like. Of those, colloidal silica is preferred. As the colloidal silica, for example, colloidal silica produced by a method described in JP-A-2003-109921 or the like may be used.

(C) The absolute value of the zeta potential of each of the abrasive grains is preferably 5 mV or more, more preferably 10 mV or more, particularly preferably 15 mV or more. When the absolute value of the zeta potential of each of (C) the abrasive grains is 5 mV or more, the abrasive grains can be homogeneously and stably dispersed by virtue of electrostatic repulsion therebetween. Such abrasive grains having homogenized dispersibility hardly cause aggregation in the chemical mechanical polishing composition, and hence can improve the storage stability of the chemical mechanical polishing composition. With this, in a chemical mechanical polishing step, the planarity of the surface to be polished can be easily secured, and polishing flaws, such as scratches, on the surface to be polished can be reduced. The zeta potential of each of the abrasive grains in the chemical mechanical polishing composition may be measured using a zeta potential measurement apparatus (manufactured by Dispersion Technology Inc., model: DT300) or the like.

As a method of adjusting the absolute value of the zeta potential of each of the silica particles to 5 mV or more, there are given, for example, a method involving modifying the surfaces of the silica particles described in WO 2011/093153, J Ind. Eng. Chem., Vol. 12, No. 6, (2006) 911-917, or the like, and a method involving combining a silica producing compound and an aminosilane compound to produce silica particles described in JP-A-2017-524767 or the like. Of those methods, a method involving modifying the surfaces of the silica particles is preferred.

An example of the method involving modifying the surfaces of the silica particles is a method involving fixing at least one functional group selected from a group consisting of a sulfo group and a salt thereof to each of the surfaces of the silica particles through a covalent bond. Specifically, this can be achieved by sufficiently stirring the silica particles and a mercapto group-containing silane coupling agent in an acidic medium, to thereby covalently bond the mercapto group-containing silane coupling agent to each of the surfaces of the silica particles. Examples of the mercapto group-containing silane coupling agent include 3-mercaptopropylmethyldimethoxysilane and 3-mercaptopropyltrimethoxysilane. After that, an appropriate amount of hydrogen peroxide is further added and the resultant mixture is sufficiently left to stand. Thus, silica particles each having at least one functional group selected from a group consisting of a sulfo group and a salt thereof may be obtained. The zeta potential of each of the silica particles may be appropriately adjusted by increasing or reducing the addition amount of the mercapto group-containing silane coupling agent.

The thus obtained silica particles are silica particles each having at least one functional group selected from a group consisting of a sulfo group and a salt thereof fixed to the surface thereof through a covalent bond, and do not include silica particles each having a compound having at least one functional group selected from a group consisting of a sulfo group and a salt thereof physically or ionically adsorbed to the surface thereof. In addition, the term “salt of a sulfo group” refers to a functional group obtained by substituting a hydrogen ion contained in the sulfo group (—SO₃H) with a cation, such as a metal ion or an ammonium ion.

The surfaces of the thus obtained silica particles are each negatively charged with the functional group, and the affinity thereof for the surface of the wiring metal is improved when the wiring metal is copper or a copper alloy. As a result, the silica particles can particularly increase the rate at which copper or the copper alloy is polished while reducing damage to the surface to be polished.

Another example of the method involving modifying the surfaces of the silica particles is a method involving sufficiently stirring the silica particles and an amino group-containing silane coupling agent in an alkaline medium to modify the surfaces of the silica particles, to thereby produce amino group-modified silica particles. Examples of the amino group-containing silane coupling agent include 3-aminopropyltrimethoxysilane, 3-aminopropyltriethoxysilane, N-2-(aminoethyl)-3-aminopropylmethyldimethoxysilane, N-2-(aminoethyl)-3-aminopropyltrimethoxysilane, 3-triethoxysilyl-N-(1,3-dimethyl-butylidene)propylamine, N-phenyl-3-aminopropyltrimethoxysilane, and N-(vinylbenzyl)-2-aminoethyl-3-aminopropyltrimethoxy silane hydrochloride.

The average particle diameter of the component (C) is preferably 5 nm or more and 300 nm or less, more preferably 20 nm or more and 70 nm or less. When the average particle diameter of the component (C) falls within the above-mentioned range, the polishing rate for a circuit board including a resin substrate on which a wiring layer containing copper or a copper alloy is provided can be improved in some cases. Herein, the average particle diameter of the component (C) may be determined by measurement with a particle size distribution analyzer that utilizes a dynamic light scattering method as a measurement principle. Examples of the particle diameter measurement apparatus based on the dynamic light scattering method include a nanoparticle analyzer Delsa Nano S manufactured by Beckman Coulter, Inc. and Zetasizer Nano ZS manufactured by Malvern Panalytical Ltd. The average particle diameter measured using the dynamic light scattering method represents the average particle diameter of secondary particles each formed by aggregation of a plurality of primary particles.

The lower limit value of the content of the component (C) is preferably 0.1 mass %, more preferably 0.5 mass %, particularly preferably 1 mass % with respect to the total mass of the chemical mechanical polishing composition. When the content of the component (C) is equal to or higher than the above-mentioned value, the polishing rate for a circuit board including a resin substrate on which a wiring layer containing copper or a copper alloy is provided can be improved in some cases. Meanwhile, the upper limit value of the content of the component (C) is preferably 20 mass %, more preferably 15 mass %, particularly preferably 12 mass % with respect to the total mass of the chemical mechanical polishing composition. When the content of the component (C) is equal to or lower than the above-mentioned value, satisfactory storage stability can be easily obtained, and hence the planarity of the surface to be polished and the reduction of polishing flaws can be achieved in the chemical mechanical polishing step in some cases.

### 1.4. Other Additives

The chemical mechanical polishing composition may contain, as required, an oxidizing agent, a surfactant, a nitrogen-containing heterocyclic compound, a water-soluble polymer, a pH adjusting agent, and the like, in addition to water serving as a main liquid medium.

<Water>

The chemical mechanical polishing composition contains water as the main liquid medium. The water is not particularly limited, but is preferably pure water. The water only needs to be blended as the balance excluding the above-mentioned constituent materials of the chemical mechanical polishing composition, and the content of the water is not particularly limited.

<Oxidizing Agent>

The chemical mechanical polishing composition may contain an oxidizing agent. When the oxidizing agent is contained, a resin film or the wiring metal can be oxidized to promote a complexation reaction with a polishing liquid component, to thereby form a brittle modified layer on the surface to be polished, and thus polishing can be facilitated in some cases.

Examples of the oxidizing agent include: peroxides, such as hydrogen peroxide, peracetic acid, perbenzoic acid, and tert-butyl hydroperoxide; permanganic acid compounds, such as potassium permanganate; dichromic acid compounds, such as potassium dichromate; halogen acid compounds, such as potassium iodate; nitric acid compounds, such as nitric acid and iron nitrate; perhalogen acid compounds, such as perchloric acid; persulfates, such as ammonium persulfate; and heteropolyacids. Of those oxidizing agents, hydrogen peroxide is particularly preferred. Those oxidizing agents may be used alone or in combination thereof.

When the oxidizing agent is contained, the content of the oxidizing agent is preferably from 1 mass % to 30 mass %, more preferably from 5 mass % to 25 mass % with respect to the total mass of the chemical mechanical polishing composition.

<Surfactant>

The chemical mechanical polishing composition may contain a surfactant. The surfactant can impart an appropriate viscous property to the chemical mechanical polishing composition in some cases.

The surfactant is not particularly limited, and examples thereof include an anionic surfactant, a cationic surfactant, and a nonionic surfactant. Examples of the anionic surfactant include: carboxylates, such as a fatty acid soap and an alkyl ether carboxylate; sulfonates, such as an alkylbenzene sulfonate, an alkylnaphthalene sulfonate, and an α-olefin sulfonate; sulfates, such as a higher alcohol sulfate, an alkyl ether sulfate, and a polyoxyethylene alkylphenyl ether sulfate; and fluorine-containing surfactants, such as a perfluoroalkyl compound. Examples of the cationic surfactant include an aliphatic amine salt and an aliphatic ammonium salt. Examples of the nonionic surfactant include: nonionic surfactants each having a triple bond, such as acetylene glycol, an acetylene glycol ethylene oxide adduct, and acetylene alcohol; and polyethylene glycol-type surfactants. Those surfactants may be used alone or in combination thereof.

When the surfactant is contained, the content of the surfactant is preferably from 0.001 mass % to 5 mass %, more preferably from 0.001 mass % to 3 mass %, particularly preferably from 0.01 mass % to 1 mass % with respect to the total mass of the chemical mechanical polishing composition.

<Nitrogen-Containing Heterocyclic Compound>

The chemical mechanical polishing composition may contain a nitrogen-containing heterocyclic compound. When the nitrogen-containing heterocyclic compound is contained, excessive etching of the wiring metal can be suppressed, and besides, surface roughening after polishing can be prevented in some cases.

The nitrogen-containing heterocyclic compound is an organic compound containing at least one heterocycle selected from a five-membered heterocycle and a six-membered heterocycle each having at least one nitrogen atom. Examples of the heterocycle include: five-membered heterocycles, such as a pyrrole structure, an imidazole structure, and a triazole structure; and six-membered heterocycles, such as a pyridine structure, a pyrimidine structure, a pyridazine structure, and a pyrazine structure. The heterocycle may form a condensed ring. Specific examples thereof include an indole structure, an isoindole structure, a benzimidazole structure, a benzotriazole structure, a quinoline structure, an isoquinoline structure, a quinazoline structure, a cinnoline structure, a phthalazine structure, a quinoxaline structure, and an acridine structure. Of the heterocyclic compounds having such structures, a heterocyclic compound having a pyridine structure, a quinoline structure, a benzimidazole structure, or a benzotriazole structure is preferred.

Specific examples of the nitrogen-containing heterocyclic compound include aziridine, pyridine, pyrimidine, pyrrolidine, piperidine, pyrazine, triazine, pyrrole, imidazole, indole, quinoline, isoquinoline, benzoisoquinoline, purine, pteridine, triazole, triazolidine, benzotriazole, and carboxybenzotriazole, and derivatives having those skeletons. Of those, at least one selected from benzotriazole, triazole, imidazole, and carboxybenzotriazole is preferred. Those nitrogen-containing heterocyclic compounds may be used alone or in combination thereof.

When the nitrogen-containing heterocyclic compound is contained, the content of the nitrogen-containing heterocyclic compound is preferably from 0.05 mass % to 2 mass %, more preferably from 0.1 mass % to 1 mass %, particularly preferably from 0.2 mass % to 0.6 mass % with respect to the total mass of the chemical mechanical polishing composition.

<Water-Soluble Polymer>

The chemical mechanical polishing composition may contain a water-soluble polymer. When the water-soluble polymer is contained, the water-soluble polymer can adsorb onto the surface to be polished of a circuit board including a resin substrate on which a wiring layer containing copper or a copper alloy is provided to reduce polishing friction in some cases. The water-soluble polymer is preferably a polycarboxylic acid, more preferably at least one selected from a group consisting of polyacrylic acid, polymaleic acid, and copolymers thereof.

The weight-average molecular weight (Mw) of the water-soluble polymer is preferably 1,000 or more and 1,000,000 or less, more preferably 3,000 or more and 800,000 or less. When the weight-average molecular weight of the water-soluble polymer falls within the above-mentioned range, the water-soluble polymer can easily adsorb onto the surface to be polished of a circuit board including a resin substrate on which a wiring layer containing copper or a copper alloy is provided, and hence the polishing friction can be further reduced in some cases. As a result, the occurrence of polishing flaws on the surface to be polished can be more effectively reduced in some cases. The term “weight-average molecular weight (Mw)” as used herein refers to a weight-average molecular weight in terms of polyethylene glycol measured by gel permeation chromatography (GPC).

The content of the water-soluble polymer is preferably from 0.01 mass % to 1 mass %, more preferably from 0.03 mass % to 0.5 mass % with respect to the total mass of the chemical mechanical polishing composition.

The content of the water-soluble polymer is preferably adjusted so that the viscosity of the chemical mechanical polishing composition may be less than 10 mPa·s, though the content depends on the weight-average molecular weight (Mw) of the water-soluble polymer. When the viscosity of the chemical mechanical polishing composition is less than 10 mPa·s, a circuit board including a resin substrate on which a wiring layer containing copper or a copper alloy is provided can be easily polished at a high rate, and by virtue of the appropriate viscosity, the chemical mechanical polishing composition can be stably supplied onto an abrasive cloth.

<pH Adjusting Agent>

The chemical mechanical polishing composition may contain a pH adjusting agent. When the pH adjusting agent is contained, it sometimes becomes easy to adjust the pH to from 1 to 3 while appropriately adjusting the addition amount of the component (A) or the component (B) so as to provide the desired effects of the invention. An inorganic acid may be used as the pH adjusting agent. Examples of the inorganic acid include hydrochloric acid, nitric acid, sulfuric acid, phosphoric acid, phosphonic acid, and polyphosphoric acid. Of those inorganic acids, phosphoric acid, phosphonic acid, and polyphosphoric acid are particularly preferred. Those pH adjusting agents may be used alone or in combination thereof.

1.5. pH

The pH value of the chemical mechanical polishing composition is from 1 to 3, and is preferably from 1.1 to 2.4, more preferably from 1.2 to 2. When the pH falls within the above-mentioned range, a circuit board including a resin substrate on which a wiring layer containing copper or a copper alloy is provided can be easily polished at a high rate, the planarity of the surface to be polished can be easily secured, and corrosion of the wiring metal can be suppressed.

The pH of the chemical mechanical polishing composition may be adjusted by, for example, appropriately increasing or reducing the addition amounts of the component (A), the component (B), and the pH adjusting agent.

In the invention, the pH refers to a hydrogen ion exponent, and its value may be measured under the conditions of 25° C. and 1 atm using a commercially available pH meter (e.g., a tabletop pH meter manufactured by Horiba, Ltd.).

### 1.6. Applications

As described above, the chemical mechanical polishing composition allows a circuit board including a resin substrate on which a wiring layer containing copper or a copper alloy is provided to be polished at a high rate, and besides, can reduce damage due to etching and corrosion on the surface to be polished of the circuit board. Accordingly, the chemical mechanical polishing composition is suitable as a polishing material for subjecting a wiring layer containing copper or a copper alloy in a circuit board including a resin substrate having arranged thereon the wiring layer containing copper or a copper alloy to chemical mechanical polishing.

### 1.7. Method of Preparing Chemical Mechanical Polishing Composition

The chemical mechanical polishing composition may be prepared by dissolving or dispersing the above-mentioned components in a liquid medium, such as water. A method of dissolving or dispersing the components is not particularly limited, and any method may be applied as long as the components can be uniformly dissolved or dispersed. In addition, the order in which the components are mixed and a mixing method therefor are also not particularly limited.

In addition, the chemical mechanical polishing composition may be prepared as an undiluted solution of a concentrated type and used by being diluted with a liquid medium, such as water, at the time of use.

### 2. Method of Manufacturing Circuit Board

The method of manufacturing a circuit board according to one embodiment of the invention includes a step of performing chemical mechanical polishing using the above-mentioned chemical mechanical polishing composition. Manufacturing steps for a circuit board and a chemical mechanical polishing apparatus are described below with reference to the drawings.

### 2.1. Manufacturing Steps for Circuit Board

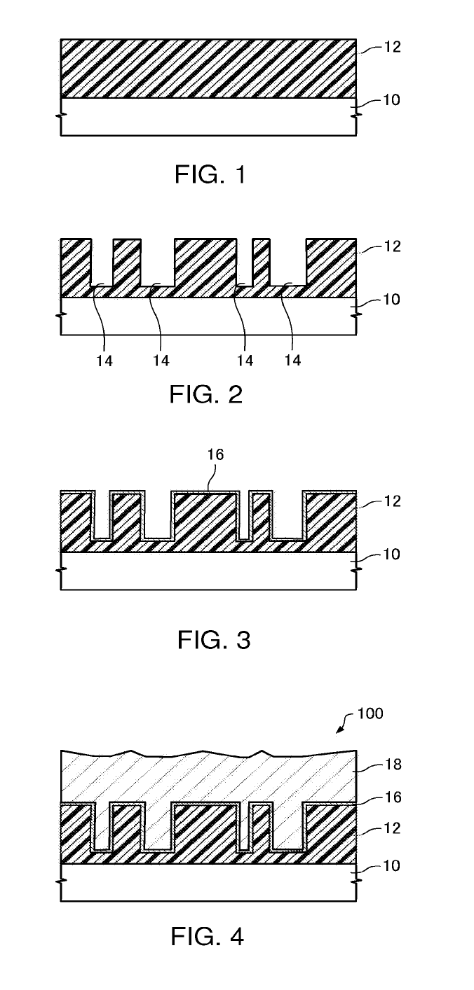

FIG. 1 to FIG. 5 are cross-sectional views for schematically illustrating steps of the method of manufacturing a circuit board. First, as illustrated in FIG. 1, a resin film 12 is formed on a base 10, such as a silicon wafer or glass. As a method of forming the resin film 12, there is given, for example, a method involving subjecting a thermosetting resin composition to spin coating on the base 10 to form a resin coating film, and heating the resin coating film at a predetermined temperature for a predetermined period of time, to thereby form the resin film 12. The resin film 12 is not limited to a stacked body formed on the base 10, and the resin film 12 may be a single-layer body.

A material for the resin film 12 is not particularly limited as long as the material has an insulating property, and for example, an epoxy resin, a phenol resin, a glass epoxy resin, a silica-filled epoxy resin, a photosensitive resist film, or a plastic may be used.

Then, as illustrated in FIG. 2, wiring depressions 14 are formed by a photolithography or etching technology. The wiring depressions 14 are formed in correspondence to the wiring layer of the circuit board.

Then, as illustrated in FIG. 3, a copper seed film 16 is formed so as to cover the surface of the resin film 12, and the bottom surface and inner wall surface of each of the wiring depressions 14. The copper seed film 16 has a bonding function of stabilizing adhesive strength between the resin film 12 and a copper film 18 as well as a role as a cathode for electroplating. As a material for the copper seed film 16, for example, tantalum, tantalum nitride, nickel, or chromium may be used. The copper seed film 16 may be formed by using a sputtering or electroless plating technology.

Then, as illustrated in FIG. 4, the copper film 18 is formed by depositing copper or a copper alloy so as to cover the surface of the copper seed film 16. The copper film 18 may be formed by using an electroplating technology. Thus, an object 100 to be treated is obtained.

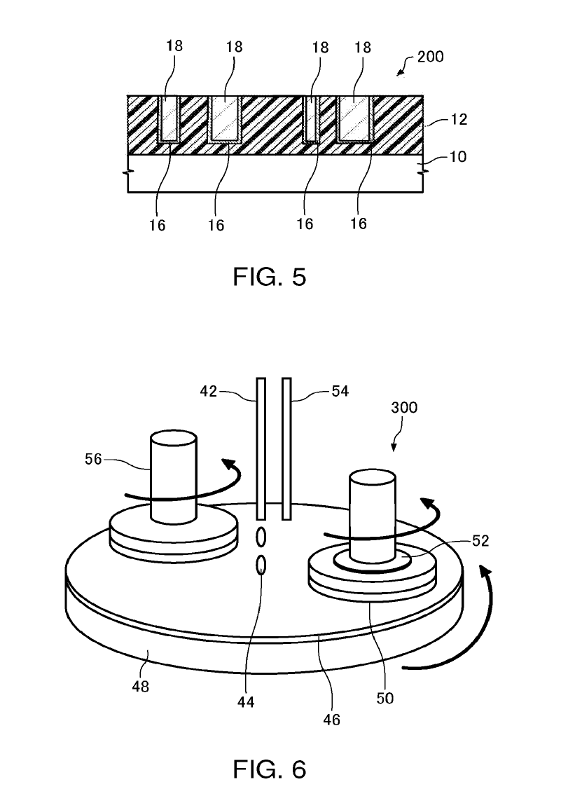

Then, as illustrated in FIG. 5, a step of subjecting excesses of the copper film 18 and the copper seed film 16 other than portions buried in the wiring depressions 14 to chemical mechanical polishing using the above-mentioned chemical mechanical polishing composition is performed. The above-mentioned chemical mechanical polishing composition allows a circuit board including a resin substrate on which a wiring layer containing copper or a copper alloy is provided to be polished at a high rate, and besides, can reduce damage due to etching and corrosion on the surface to be polished of the circuit board. Accordingly, the circuit board can be manufactured with a high throughput, and a problem such as a connection failure hardly occurs at the time of mounting. Only an excess of the copper film 18 on the resin film 12 may be removed by the chemical mechanical polishing using the above-mentioned chemical mechanical polishing composition, or the resin film 12 and the copper film 18 may be simultaneously removed by the chemical mechanical polishing using the above-mentioned chemical mechanical polishing composition. Further, a two-stage polishing step in which the resin film 12 is then removed by chemical mechanical polishing using a chemical mechanical polishing composition for removing the resin film 12 may be carried out.

After the chemical mechanical polishing, in order to remove the abrasive grains and the like remaining on the surface to be polished, it is desired that the resultant circuit board 200 be cleaned using a cleaning liquid. Through such steps as described above, a circuit board 200 may be produced. The circuit board 200 may have a wiring layer of any shape. In addition, a plurality of circuit boards each having a wiring layer of an appropriate shape may be stacked to form a multilayer circuit board. The multilayer circuit board has a three-dimensional wiring structure in which the wiring layers of the respective circuit boards are appropriately electrically connected.

The above-mentioned manufacturing steps for a circuit board are a method involving forming the copper film 18 on the resin film 12 having a groove pattern, and then performing chemical mechanical polishing using the chemical mechanical polishing composition. However, a method involving forming a resin film on a copper film having a groove pattern, and then performing chemical mechanical polishing using the chemical mechanical polishing composition may be adopted.

### 2.2. Chemical Mechanical Polishing Apparatus

For the above-mentioned chemical mechanical polishing step, for example, a chemical mechanical polishing apparatus 300 as illustrated in FIG. 6 may be used. FIG. 6 is a perspective view for schematically illustrating the chemical mechanical polishing apparatus 300. The above-mentioned polishing step is performed by supplying a slurry (chemical mechanical polishing composition) 44 from a slurry supply nozzle 42, and while rotating a turntable 48 having attached thereto an abrasive cloth 46, bringing a carrier head 52 holding a circuit board 50 into abutment against the abrasive cloth 46. In FIG. 4, a water supply nozzle 54 and a dresser 56 are also illustrated.

The polishing load of the carrier head 52 may be selected within the range of from 0.7 psi to 70 psi, and is preferably from 1.5 psi to 35 psi. In addition, the rotation speed of each of the turntable 48 and the carrier head 52 may be appropriately selected within the range of from 10 rpm to 400 rpm, and is preferably from 30 rpm to 150 rpm. The flow rate of the slurry (chemical mechanical polishing composition) 44 to be supplied from the slurry supply nozzle 42 may be selected within the range of from 10 mL/min to 1,000 mL/min, and is preferably from 50 mL/min to 400 mL/min.

Examples of commercially available products of the polishing apparatus include: a model EPO-112 or EPO-222 manufactured by Ebara Corporation; a model LGP-510 or LGP-552 manufactured by Lap master SFT Ltd.; a model Mirra or Reflexion manufactured by Applied Materials Inc.; a model POLI-400L manufactured by G&P Technology; and a model Reflexion LK manufactured by AMAT.

### 3. Examples

The invention is described below by way of Examples. However, the invention is by no means limited to these Examples. The units “parts” and “%” used in Examples of the invention are by mass unless otherwise indicated.

### 3.1. Preparation of Aqueous Dispersion Containing Abrasive Grains

### (1) Preparation of Aqueous Dispersion Containing Colloidal Silica A1

A flask having a volume of 2,000 cm³ was loaded with 100 g of 28% ammonia water, 160 g of ion-exchanged water, and 1,250 g of methanol, and the contents were increased in temperature to 35° C. under stirring at 180 rpm. To the solution, a mixed liquid of 160 g of tetraethoxysilane and 40 g of methanol was slowly added dropwise to provide a colloidal silica/alcohol dispersion. Then, with an evaporator, an operation of removing an alcohol content while adding ion-exchanged water to the dispersion at 80° C. was repeated several times to remove the alcohol in the dispersion. Thus, an aqueous dispersion containing colloidal silica A1 having a solid content concentration of 15% was prepared.

Part of the aqueous dispersion was taken and diluted with ion-exchanged water to prepare a sample. The arithmetic average diameter of the sample was measured as an average particle diameter using a dynamic light scattering particle diameter measurement apparatus (manufactured by Horiba, Ltd., model: LB550), and was found to be 67 nm. In addition, through the use of a zeta potential measurement apparatus (manufactured by Dispersion Technology Inc., model: DT300), the particles were each found to have a zeta potential of 1 mV when diluted to 3% and adjusted to a pH of 2.4.

### (2) Preparation of Aqueous Dispersion Containing Colloidal Silica A2

A flask having a volume of 2,000 cm³ was loaded with 100 g of 28% ammonia water, 160 g of ion-exchanged water, and 1,250 g of methanol, and the contents were increased in temperature to 50° C. under stirring at 180 rpm. To the solution, a mixed liquid of 160 g of tetraethoxysilane and 40 g of methanol was slowly added dropwise to provide a colloidal silica/alcohol dispersion. Then, with an evaporator, an operation of removing an alcohol content while adding ion-exchanged water to the dispersion at 80° C. was repeated several times to remove the alcohol in the dispersion. Thus, an aqueous dispersion containing colloidal silica A2 having a solid content concentration of 15% was prepared.

Part of the aqueous dispersion was taken and diluted with ion-exchanged water to prepare a sample. The arithmetic average diameter of the sample was measured as an average particle diameter using a dynamic light scattering particle diameter measurement apparatus (manufactured by Horiba, Ltd., model: LB550), and was found to be 30 nm. In addition, through the use of a zeta potential measurement apparatus (manufactured by Dispersion Technology Inc., model: DT300), the particles were each found to have a zeta potential of 1 mV when diluted to 3% and adjusted to a pH of 2.4.

### (3) Preparation of Aqueous Dispersion Containing Sulfo Group-Modified Colloidal Silica A3

1,000 g of the aqueous dispersion containing the colloidal silica A1 prepared above was increased in temperature to 60° C. under stirring. Further, 1 g of a mercapto group-containing silane coupling agent (manufactured by Shin-Etsu Chemical Co., Ltd., product name: KBE803) was added, and stirring was further continued for 2 hours. After that, 8 g of 35% hydrogen peroxide water was added, and the mixture was kept at 60° C. under stirring for 8 hours. After that, the resultant was cooled to room temperature to provide an aqueous dispersion of sulfo group-modified colloidal silica A3.

Part of the aqueous dispersion was taken and diluted with ion-exchanged water to prepare a sample. The arithmetic average diameter of the sample was measured as an average particle diameter using a dynamic light scattering particle diameter measurement apparatus (manufactured by Horiba, Ltd., model: LB550), and was found to be 68 nm. In addition, through the use of a zeta potential measurement apparatus (manufactured by Dispersion Technology Inc., model: DT300), the particles were each found to have a zeta potential of −34 mV when diluted to 3% and adjusted to a pH of 2.4.

### (4) Preparation of Aqueous Dispersion Containing Sulfo Group-Modified Colloidal Silica A4

1,000 g of the aqueous dispersion containing the colloidal silica A2 prepared above was increased in temperature to 60° C. under stirring. Further, 1 g of a mercapto group-containing silane coupling agent (manufactured by Shin-Etsu Chemical Co., Ltd., product name: KBE803) was added, and stirring was further continued for 2 hours. After that, 8 g of 35% hydrogen peroxide water was added, and the mixture was kept at 60° C. under stirring for 8 hours. After that, the resultant was cooled to room temperature to provide an aqueous dispersion of sulfo group-modified colloidal silica A4.

Part of the aqueous dispersion was taken and diluted with ion-exchanged water to prepare a sample. The arithmetic average diameter of the sample was measured as an average particle diameter using a dynamic light scattering particle diameter measurement apparatus (manufactured by Horiba, Ltd., model: LB550), and was found to be 31 nm. In addition, through the use of a zeta potential measurement apparatus (manufactured by Dispersion Technology Inc., model: DT300), the particles were each found to have a zeta potential of −34 mV when diluted to 3% and adjusted to a pH of 2.4.

### (5) Preparation of Aqueous Dispersion Containing Amino Group-Modified Colloidal Silica A5

28% ammonia water was added to 1,000 g of the aqueous dispersion containing the colloidal silica A1 prepared above to adjust its pH to from 10.0 to 10.5. To the solution, a mixed liquid of 19 g of methanol and 1 g of 3-aminopropyltrimethoxysilane was added dropwise over 10 minutes while the liquid temperature was kept at 30° C. After that, the resultant was refluxed under normal pressure for 2 hours to provide an aqueous dispersion containing amino group-modified colloidal silica A5.

Part of the aqueous dispersion was taken and diluted with ion-exchanged water to prepare a sample. The arithmetic average diameter of the sample was measured as an average particle diameter using a dynamic light scattering particle diameter measurement apparatus (manufactured by Horiba, Ltd., model: LB550), and was found to be 68 nm. In addition, through the use of a zeta potential measurement apparatus (manufactured by Dispersion Technology Inc., model: DT300), the particles were each found to have a zeta potential of +29 mV when diluted to 3% and adjusted to a pH of 2.4.

### 3.2. Preparation of Chemical Mechanical Polishing Composition

A predetermined amount of any one of the aqueous dispersions containing abrasive grains prepared above was loaded into a polyethylene bottle having a volume of 1 liter. Compounds shown in Table 1 or Table 2, and 0.5 part by mass of benzotriazole were added thereto at a total of 100 parts by mass, and the contents were sufficiently stirred. After that, phosphoric acid was added as a pH adjusting agent to adjust the pH to a value shown in Table 1 or Table 2. After that, the resultant was filtered through a filter having a pore diameter of 0.3 μm to provide chemical mechanical polishing compositions of Examples 1 to 15 and Comparative Examples 1 to 6. For each of the thus obtained chemical mechanical polishing compositions, the zeta potential of each of the abrasive grains was measured using a zeta potential measurement apparatus (manufactured by Dispersion Technology Inc., model: DT300). The results are also shown in Table 1 and Table 2.

### 3.3. Evaluation Methods

### 3.3.1. Evaluation of Polishing Rate

With the use of any one of the chemical mechanical polishing compositions prepared above, a test piece obtained by cutting a copper-plated substrate having no wiring pattern on a resin substrate to 4 cm×4 cm was used as an object to be polished, and subjected to a chemical mechanical polishing test under the following polishing conditions for 2 minutes. Evaluation criteria therefor are as described below. The results are also shown in Table 1 and Table 2.

<Polishing Conditions>
Polishing apparatus: model POLI-400L manufactured by G&P Technology
Polishing pad: IC1000 manufactured by Nitta Haas Incorporated
Supply rate of chemical mechanical polishing composition: 100 mL/min
Surface plate rotation speed: 100 rpm
Head rotation speed: 90 rpm
Head pressure: 3 psi

Polishing rate (μm/min)=

((weight of copper-plated substrate before polishing−weight of

copper-plated substrate after polishing)/(density of copper×area of copper-plated

substrate))/polishing time

<Evaluation Criteria>

The case where the polishing rate is 8 μm/min or more is extremely practical because the polishing rate is extremely large, and hence treatment can be performed at a high rate in actual polishing of a printed board. Therefore, such case was judged as extremely satisfactory, and represented by AA in Table 1 and Table 2.

The case where the polishing rate is 4 μm/min or more and less than 8 μm/min is practical because the polishing rate is large, and hence treatment can be performed at a high rate in actual polishing of a printed board. Therefore, such case was judged as satisfactory, and represented by A in Table 1 and Table 2.

In the case where the polishing rate is 2 μm/min or more and less than 4 μm/min, the polishing rate is rather small, but practical use is possible, though process optimization is needed in actual polishing of a printed board. Therefore, such case was judged as relatively satisfactory, and represented by B in Table 1 and Table 2.

In the case where the polishing rate is less than 2 μm/min, the polishing rate is small, and hence practical use is difficult. Therefore, such case was judged as unsatisfactory, and represented by C in Table 1 and Table 2.

### 3.3.2. Evaluation of Etching Rate

### <Evaluation Method for Etching Rate>

A test piece obtained by cutting a copper-plated substrate having no wiring pattern on a resin substrate to 4 cm×4 cm, similar to the substrate for the evaluation of the polishing rate was used as an object to be polished, and immersed in any one of the chemical mechanical polishing compositions under room temperature for 2 minutes, and the etching rate of the copper film was measured. Evaluation criteria therefor are as described below. The results are also shown in Table 1 and Table 2. The etching rate was measured in the same manner as in the polishing rate evaluation.

Etching rate (nm/min)=

((weight of copper-plated substrate before polishing−weight of

copper-plated substrate after polishing)/(density of copper×area of copper-plated

substrate))/polishing time

<Evaluation Criteria>

The case where the etching rate is 0 nm/min or more and less than 50 nm/min is extremely practical because the etching rate is extremely small, and hence its balance with the polishing rate can be easily secured in actual polishing of a printed board. Therefore, such case was judged as extremely satisfactory, and represented by A in Table 1 and Table 2.

In the case where the etching rate is 50 nm/min or more and less than 150 nm/min, the etching rate is rather large, but practical use is possible, though its balance with the polishing rate needs to be secured in actual polishing of a printed board. Therefore, such case was judged as satisfactory, and represented by B in Table 1 and Table 2.

In the case where the etching rate is 150 nm/min or more, the etching rate is large, and hence practical use is difficult. Therefore, such case was judged as unsatisfactory, and represented by C in Table 1 and Table 2.

### 3.3.3. Evaluation of Surface State

<Production of Evaluation Substrate>

An 8-inch silicon wafer was spin-coated with WPR-1201 (manufactured by JSR Corporation: negative photosensitive insulating film), and then the resultant was heated using a hot plate at 110° C. for 3 minutes to produce a uniform resin coating film having a thickness of 20 μm on the silicon wafer. Then, an aligner (manufactured by SUSS MicroTec SE, model: MA-200) was used to perform exposure to ultraviolet light radiated from a high-pressure mercury lamp so as to achieve an exposure of 500 mJ/cm² at a wavelength of 365 nm. After that, the resultant was baked (PEB) using a hot plate at 110° C. for 3 minutes, and developed through immersion in an aqueous solution of tetramethylammonium hydroxide having a concentration of 2.38 mass % at 23° C. for 120 seconds. After that, the resultant was heated at 190° C. for 1 hour using a convection oven to cure the resin coating film to form an insulating film. After that, a copper seed layer was formed on the insulating resin cured film by electroless plating, and then a copper plating layer having a thickness of 30 μm was formed by an electroplating method. Thus, a substrate having a groove pattern having buried therein copper was produced.

<Evaluation Method for Surface State>

A test piece obtained by cutting the surface to be polished of the wafer with a copper film having a diameter of 8 inches obtained above to 4 cm×4 cm was used as an object to be polished and subjected to a chemical mechanical polishing test for 4 minutes under the same conditions as in the “evaluation of polishing rate” except for using the chemical mechanical polishing composition described in Example 1, to thereby expose a circuit pattern. After that, the pattern-exposed substrate was immersed in each of the chemical mechanical polishing compositions of Examples and Comparative Examples under the same conditions as in the “evaluation of etching rate” for 5 minutes, and then the copper pattern surface was observed using a laser microscope (manufactured by Olympus Corporation, model: OLS4000). A case in which the copper pattern was free of discoloration and losses was represented by A, a case in which the copper pattern had partial discoloration and losses was represented by B, and a case in which the copper pattern had considerable discoloration and losses was represented by C. The results are shown in Table 1 and Table 2.

### 3.4. Evaluation Results

The compositions, physical properties, and evaluation results of the chemical mechanical polishing compositions are shown in Table 1 and Table 2 below.

TABLE 1

| | | | Example 1 | Example 2 | Example 3 | Example 4 | Example 5 | Example 6 |
|---|---|---|---|---|---|---|---|---|
| Chemical | Component (A) | Kind | Maleic | Maleic | Maleic | L-Tartaric | Malic | Maleic |
| mechanical | | | acid | acid | acid | acid | acid | acid |
| polishing | | Complex stability | 3.9 | 3.9 | 3.9 | 3.2 | 3.4 | 3.9 |
| composition | | constant | | | | | | |
| | | Content (part(s) | 5 | 5 | 5 | 5 | 5 | 5 |
| | | by mass) | | | | | | |
| | Component (B) | Kind | Ammonia | KOH | MEA | Ammonia | Ammonia | Ammonia |
| | | Content (part(s) | 0.4 | 0.8 | 1.0 | 0.4 | 0.4 | 0.2 |
| | | by mass) | | | | | | |
| | Component (C) | Kind | A3 | A3 | A3 | A3 | A3 | A3 |
| | | Content (part(s) | 2 | 2 | 2 | 2 | 2 | 2 |
| | | by mass) | | | | | | |
| | Oxidizing agent | Hydrogen peroxide | 23 | 23 | 23 | 23 | 23 | 23 |
| | | (part(s) by mass) | | | | | | |
| | Liquid medium | Water (part(s) | Balance | Balance | Balance | Balance | Balance | Balance |
| | | by mass) | | | | | | |
| Physical | pH | | 1.5 | 1.5 | 1.5 | 2.1 | 2.1 | 1.2 |
| property | Mass ratio (M_{A}/M_{B}) | | 12.5 | 6.3 | 5.0 | 12.5 | 12.5 | 25.0 |
| item | Zeta potential (mV) | | −14 | −15 | −14 | −17 | −16 | −14 |
| Evaluation | Polishing rate | Copper film RR | 9.1 | 8.8 | 8.7 | 5.8 | 5.5 | 5.1 |
| item | evaluation | (μm/min) | | | | | | |
| | | Evaluation result | AA | AA | AA | A | A | A |
| | Etching rate | Etching rate | 60 | 85 | 118 | 50 | 16 | 95 |
| | evaluation | (nm/min) | | | | | | |
| | | Evaluation result | B | B | B | B | A | B |

| | | | | | | |
|---|---|---|---|---|---|---|
| Surface state | B | B | B | A | A | B |

| | | | Example 7 | Example 8 | Example 9 | Example 10 |
|---|---|---|---|---|---|---|
| Chemical | Component (A) | Kind | Maleic | Maleic | Maleic | Maleic |
| mechanical | | | acid | acid | acid | acid |
| polishing | | Complex stability | 3.9 | 3.9 | 3.9 | 3.9 |
| composition | | constant | | | | |
| | | Content (part(s) | 5 | 5 | 5 | 5 |
| | | by mass) | | | | |
| | Component (B) | Kind | Ammonia | Ammonia | Ammonia | Ammonia |
| | | Content (part(s) | 0.8 | 0.4 | 0.4 | 0.4 |
| | | by mass) | | | | |
| | Component (C) | Kind | A3 | A3 | A4 | A5 |
| | | Content (part(s) | 2 | 10 | 10 | 2 |
| | | by mass) | | | | |
| | Oxidizing agent | Hydrogen peroxide | 23 | 23 | 23 | 23 |
| | | (part(s) by mass) | | | | |
| | Liquid medium | Water (part(s) | Balance | Balance | Balance | Balance |
| | | by mass) | | | | |
| Physical | pH | | 1.5 | 1.5 | 1.5 | 1.5 |
| property | Mass ratio (M_{A}/M_{B}) | | 6.3 | 12.5 | 12.5 | 12.5 |
| item | Zeta potential (mV) | | −15 | −14 | −12 | +11 |
| Evaluation | Polishing rate | Copper film RR | 10.7 | 10.1 | 6.1 | 8.4 |
| item | evaluation | (μm/min) | | | | |
| | | Evaluation result | AA | AA | A | AA |
| | Etching rate | Etching rate | 29 | 58 | 55 | 60 |
| | evaluation | (nm/min) | | | | |
| | | Evaluation result | A | B | B | B |

| | | | | |
|---|---|---|---|---|
| Surface state | B | B | B | B |

TABLE 2

| | | | | | | | | Compar- |
|---|---|---|---|---|---|---|---|---|
| | | | | | | | | ative |
| | | | Example 11 | Example 12 | Example 13 | Example 14 | Example 15 | Example 1 |
| Chemical | Component (A) | Kind | Maleic | Maleic | Maleic | Maleic | Maleic | Maleic |
| mechanical | | | acid | acid | acid | acid | acid | acid |
| polishing | | Complex stability | 3.9 | 3.9 | 3.9 | 3.9 | 3.9 | 3.9 |
| composition | | constant | | | | | | |
| | | Content (part(s) | 3.0 | 10.0 | 15.0 | 2.5 | 5.0 | 5.0 |
| | | by mass) | | | | | | |
| | | Kind | | | | L-Tartaric | | |
| | | | | | | acid | | |
| | | Complex stability | | | | 3.20 | | |
| | | constant | | | | | | |
| | | Content (part(s) | | | | 2.5 | | |
| | | by mass) | | | | | | |
| | Component (B) | Kind | Ammonia | Ammonia | Ammonia | Ammonia | Ammonia | |
| | | Content (part(s) | 0.4 | 0.4 | 0.4 | 0.4 | 0.4 | |
| | | by mass) | | | | | | |
| | | Kind | | | | | | |
| | | Content (part(s) | | | | | | |
| | | by mass) | | | | | | |
| | Component (C) | Kind | A3 | A3 | A3 | A3 | A1 | A3 |
| | | Content (part(s) | 2 | 2 | 2 | 2 | 2 | 2 |
| | | by mass) | | | | | | |
| | Oxidizing agent | Hydrogen peroxide | 23 | 23 | 23 | 23 | 23 | 23 |
| | | (part(s) by mass) | | | | | | |
| | Liquid medium | Water (part(s) | Balance | Balance | Balance | Balance | Balance | Balance |
| | | by mass) | | | | | | |
| Physical | pH | | 1.5 | 1.5 | 1.5 | 1.7 | 1.8 | 1.1 |
| property | Mass ratio (M_{A}/M_{B}) | | 7.5 | 25.0 | 37.5 | 12.5 | 12.5 | — |
| item | Zeta potential (mV) | | −14 | −15 | −15 | −16 | −3 | −14 |
| Evaluation | Polishing rate | Copper film RR | 8.1 | 9.4 | 9.3 | 7.4 | 7.1 | 0.7 |
| item | evaluation | (μm/min) | | | | | | |
| | | Evaluation result | AA | AA | AA | A | A | C |
| | Etching rate | Etching rate | 11 | 45 | 120 | 55 | 52 | 51 |
| | evaluation | (nm/min) | | | | | | |
| | | Evaluation result | A | A | B | B | B | B |

| | | | | | | |
|---|---|---|---|---|---|---|
| Surface state | B | B | B | A | B | C |

| | | | Compar- | Compar- | Compar- | Compar- | Compar- |
|---|---|---|---|---|---|---|---|
| | | | ative | ative | ative | ative | ative |
| | | | Example 2 | Example 3 | Example 4 | Example 5 | Example 6 |
| Chemical | Component (A) | Kind | Citric | Citric | Malic | Glycine | Maleic |
| mechanical | | | acid | acid | acid | | acid |
| polishing | | Complex stability | 6.10 | 6.10 | 3.4 | 8.22 | 3.9 |
| composition | | constant | | | | | |
| | | Content (part(s) | 5.0 | 5.0 | 5.0 | 5.0 | 5.0 |
| | | by mass) | | | | | |
| | | Kind | | | | | |
| | | Complex stability | | | | | |
| | | constant | | | | | |
| | | Content (part(s) | | | | | |
| | | by mass) | | | | | |
| | Component (B) | Kind | Ammonia | Ammonia | | Ammonia | Ammonia |
| | | Content (part(s) | 0.4 | 1.3 | | 0.4 | 0.4 |
| | | by mass) | | | | | |
| | | Kind | | | | | KOH |
| | | Content (part(s) | | | | | 1.2 |
| | | by mass) | | | | | |
| | Component (C) | Kind | A3 | A3 | A3 | A3 | A3 |
| | | Content (part(s) | 2 | 2 | 2 | 2 | 2 |
| | | by mass) | | | | | |
| | Oxidizing agent | Hydrogen peroxide | 23 | 23 | 23 | 23 | 23 |
| | | (part(s) by mass) | | | | | |
| | Liquid medium | Water (part(s) | Balance | Balance | Balance | Balance | Balance |
| | | by mass) | | | | | |
| Physical | pH | | 1.6 | 1.5 | 1.2 | 1.5 | 3.6 |
| property | Mass ratio (M_{A}/M_{B}) | | 12.5 | 3.8 | — | 12.5 | 3.1 |
| item | Zeta potential (mV) | | −16 | −15 | −16 | −13 | −10 |
| Evaluation | Polishing rate | Copper film RR | 7.6 | 7.4 | 1.5 | 4.2 | 0.2 |
| item | evaluation | (μm/min) | | | | | |
| | | Evaluation result | A | A | C | A | C |
| | Etching rate | Etching rate | 473 | 639 | 167 | 527 | 0 |
| | evaluation | (nm/min) | | | | | |
| | | Evaluation result | C | C | C | C | A |

| | | | | | |
|---|---|---|---|---|---|
| Surface state | B | B | B | B | A |

In Table 1 and Table 2 above, KOH and MEA each used as the component (B) represent potassium hydroxide and monoethanolamine, respectively, and a numerical value for each component represents part(s) by mass. In each of Examples and Comparative Examples, the total amount of the respective components in the tables and benzotriazole is 100 parts by mass.

It was found that each of the chemical mechanical polishing compositions of Examples 1 to 15 allowed the copper film to be polished at a high rate and efficiently, was able to reduce the occurrence of damage and corrosion due to etching on the surface to be polished, and also provided a satisfactory surface state of the surface to be polished.

On the other hand, when any one of the chemical mechanical polishing compositions of Comparative Examples 1 to 6 was used, the result in any one of the items for the polishing rate of the copper film, the etching of the copper film, or the surface state was poor as compared to the chemical mechanical polishing compositions of Examples 1 to 15.

The invention is not limited to the embodiments described above, and various modifications may be made thereto. For example, the invention includes configurations that are substantially the same (for example, in function, method, and results, or in objective and effects) as the configurations described in the embodiments. The invention also includes configurations in which non-essential elements described in the embodiments are replaced by other elements. The invention also includes configurations having the same effects as those of the configurations described in the embodiments, or configurations capable of achieving the same objectives as those of the configurations described in the embodiments. The invention further includes configurations obtained by adding known art to the configurations described in the embodiments.

Some embodiments of the invention have been described in detail above, but a person skilled in the art will readily appreciate that various modifications can be made from the embodiments without materially departing from the novel teachings and effects of the invention. Accordingly, all such modifications are assumed to be included in the scope of the invention.

What is claimed is:

1. A chemical mechanical polishing composition to be used for forming a circuit board including a resin substrate on which a wiring layer containing copper or a copper alloy is provided, the chemical mechanical polishing composition comprising:
(A) at least one selected from a group consisting of carboxyl group-containing organic acids and salts thereof;
(B) a basic compound having a first acid dissociation constant (pKa) of 9 or more; and
(C) abrasive grains,
the component (A) having a complex stability constant with copper of 5 or less, and
the chemical mechanical polishing composition having a pH value of from 1 to 3.

2. The chemical mechanical polishing composition according to claim 1, wherein the abrasive grains of the component (C) each have an absolute value of a zeta potential of 5 mV or more in the chemical mechanical polishing composition.

3. The chemical mechanical polishing composition according to claim 1, wherein the component (A) contains at least one selected from a group consisting of maleic acid, tartaric acid, malic acid, and salts thereof.

4. The chemical mechanical polishing composition according to claim 1, wherein the component (B) contains at least one selected from a group consisting of a metal hydroxide, an amine, and ammonia.

5. The chemical mechanical polishing composition according to claim 1, wherein the abrasive grains of the component (C) are silica particles.

6. The chemical mechanical polishing composition according to claim 5, wherein the silica particles each have at least one functional group selected from a group consisting of a sulfo group, an amino group, and salts thereof.

7. The chemical mechanical polishing composition according to claim 1, wherein the abrasive grains of the component (C) have an average particle diameter of 40 nm or more and 100 nm or less.

8. A method of manufacturing a circuit board, the method comprising:
performing chemical mechanical polishing by using the chemical mechanical polishing composition as defined in claim 1.
